(19) United States
(12) Patent Application Publication
(10) Pub. No.: US 2012/0307449 A1
(43) Pub. Date: Dec. 6, 2012

(54) CLIMATE MANAGEMENT SYSTEM, AND MANAGEMENT METHOD AND POWER SUPPLY SYSTEM USING SAME

(75) Inventors: Yao-Feng Hsu, Taoyuan Hsien (TW); Ta-Yu Huang, Taoyuan Hsien (TW); Po-Ching Wang, Taoyuan Hsien (TW); Mao-Hsuan Jiang, Taoyuan Hsien (TW)

(73) Assignee: DELTA ELECTRONICS, INC., Taoyuan Hsien (TW)

(21) Appl. No.: 13/486,752

(22) Filed: Jun. 1, 2012

Related U.S. Application Data
(60) Provisional application No. 61/493,084, filed on Jun. 3, 2011.

(51) Int. Cl. H05K 7/20; G05D 23/19

(52) U.S. Cl. 361/692; 62/259.2; 165/206; 165/247; 361/688; 361/695

(57) ABSTRACT

A climate management system for a power supply system including a plurality of cabinets is disclosed. The climate management system comprises a plurality of climate control units connected and in communication with each other, wherein each climate control unit is disposed in a corresponding cabinet to monitor, manage and control the corresponding cabinet, wherein one of the climate control units is defined as a master climate control unit and the other of the climate control units are defined as slave climate control units; and a control system unit connected and in communication with the master climate control unit. The master climate control unit is configured to collect, process and integrate the information transmitted from the slave climate control units and report the collected, processed and integrated information to the control system unit.

### CROSS-REFERENCE TO RELATED APPLICATION

This application claims the benefit of U.S. Provisional Application No. 61/493,084 filed on Jun. 3, 2011, and entitled “CLIMATE MANAGEMENT SYSTEM AND METHOD FOR POWER SUPPLY SYSTEM”, the entirety of which is hereby incorporated by reference.

### FIELD OF THE INVENTION

The present invention relates to a management system, and more particularly to a climate management system, and a management method and a power supply system using the same.

### BACKGROUND OF THE INVENTION

With increasing development of information industries and communication networks, the services provided through communication networks are becoming more and more popular in various applications. Telecommunication systems are essential electronic equipments for use in the communication networks and include a variety of hardware and software components that may be configured to process, store, communicate and exchange information. For providing required and uninterrupted power to the telecommunication system for operation, a power supply system is employed. Generally, the telecommunication system is required to provide uninterrupted communication serves in the event of an electrical utility power outage for a predetermined period of time, so that the power supply system must employ a plurality of backup battery units disposed in cabinets of the power supply system to provide the necessary emergency power.

When battery units and/or climate devices in the cabinets of the power supply system fail or are out of control, this can cause disruption in related operations. Therefore, it is very important to monitor the status of the battery units and manage and control the climate devices, for example fan, heater, door open detector or filter sensor, inside the cabinets. However, it is a time-consuming and complex task to monitor, manage and control the battery units and climate devices in widely spaced cabinets. To resolve the problems, a climate management system is employed for the power supply system. In the conventional climate management system, all climate control units (CCUs) of the cabinets are directly and respectively coupled to a control system unit (CSU) of the master cabinet via communication networks. For enabling the communication between the control system unit (CSU) and each climate control unit (CCU), the designer needs to edit various programs according to various communication protocols between the control system unit and all climate control units. Therefore, the developmental periods of the products are prolonged and the manufacturing costs of the products are increased.

In addition, during operations of the power supply equipments of the power supply system, a great amount of heat is generated. The system stability and the use lives of these electronic devices in the cabinet are dependent on the capability of removing heat. The cabinet usually includes a fan for quickly removing heat generated during operation. The fan may provide forced airflow for exhausting warm air from the internal portion of the cabinet to the airflow outlet of the cabinet. In addition, a dust-proof element (i.e. an air filter) is usually arranged at and faces to the airflow inlet of the cabinet in order to obstruct dust from entering the internal portion of the cabinet. In a case that the dust-proof element has been used for a prolonged period, the degree of dust accumulation becomes more serious and thus the airflow induced by the fan fails to pass through the dust-proof element. Under this circumstance, the heat-removing capability of the cabinet is reduced and the performance of the cabinet is deteriorated. For providing unobstructed airflow, the dust-proof element needs to be periodically cleaned or replaced with a new one or the use life of the dust-proof element needs to be extended. Conventionally, some mechanisms are used for discriminating whether the dust-proof element needs to be replaced. However, how to transmit the notifying signal or information from the climate control units to the control system unit is not easy to be designed. In addition, it is not easy to extend the use life of the dust-proof element. Generally, the cabinet may be located outdoors and the cooling airflow introduced into the cabinet may contain relatively great quantity of dust and moisture, which may reduce the use lives of the dust-proof element and the electronic devices inside the cabinet.

It is therefore desirable to develop a climate management system, and a management method and a power supply system using the same to obviate the drawbacks encountered from the prior art.

### SUMMARY OF THE INVENTION

It is an object of the present invention to provide a climate management system, and a management method and a power supply system using the same, in which the climate control unit of the cabinet can be stand alone application or can be connected with different kinds of control system units.

It is another object of the present invention to provide a climate management system, and a management method and a power supply system using the same, in which the communication between the cabinets are performed by the climate control units of the cabinets with communication protocol for the long distance communication.

It is a further object of the present invention to provide a climate management system, and a management method and a power supply system using the same, in which the master climate control unit can collect and combine all the information from the slave climate control units and transmits the integrated information to a control system unit in analog or simple digital signals.

It is a further object of the present invention to provide a climate management system, and a management method and a power supply system using the same, in which the designer can use various control system unit in the cabinet without editing the programs according to various communication protocols between the control system unit and climate control units so that the developmental periods of the products are shortened and the manufacturing costs of the products are reduced.

It is a further object of the present invention to provide a climate management system, and a management method and a power supply system using the same, in which a cabinet of the power supply system has a waterproof and dust-reduction mechanism for reducing the dust and providing waterproof function and has an air filter sensor and a climate control unit for discriminating whether the dust-proof element needs to be replaced and issuing a notifying signal to the climate control unit.

It is a further object of the present invention to provide a climate management system, and a management method and a power supply system using the same to extend the use life of the dust-proof element, provide waterproof function of the cabinet, and reduce the acoustic noise.

In accordance with one aspect of the present invention, a climate management system for a power supply system including a plurality of cabinets is provided. The climate management system comprises a plurality of climate control units connected and in communication with each other, wherein each climate control unit is disposed in a corresponding cabinet to monitor, manage and control the corresponding cabinet, wherein one of the climate control units is defined as a master climate control unit and the other of the climate control units are defined as slave climate control units; and a control system unit connected and in communication with the master climate control unit. The master climate control unit is configured to collect, process and integrate the information transmitted from the slave climate control units and report the collected, processed and integrated information to the control system unit.

In accordance with another aspect of the present invention, a power supply system is provided. The power supply system comprises a plurality of cabinets, and a climate management system. The climate management system comprises a plurality of climate control units connected and in communication with each other, wherein each of the climate control units is disposed in a corresponding cabinet of the cabinets to monitor, manage and control the corresponding cabinet, wherein one of the climate control units is defined as a master climate control unit and the other of the climate control units are defined as slave climate control units; and a control system unit connected and in communication with the master climate control unit. The master climate control unit is configured to collect, process and integrate the information transmitted from the slave climate control units and report the collected, processed and integrated information to the control system unit.

In accordance with a further aspect of the present invention, a management method of a climate management system is provided. The climate management system is applied to a power supply system having a plurality of cabinets. The climate management system comprises a master climate control unit, a plurality of slave climate control units and a control system unit, and the master climate control unit and each slave climate control unit are respectively disposed in a corresponding cabinet. The management method comprises the steps of: (a) monitoring, managing and controlling the corresponding cabinet respectively by the master climate control unit and each slave climate control unit; (b) collecting, processing and integrating the information from the slave climate control units by the master climate control unit; and (c) reporting the collected, processed and integrated information to the control system unit by the master climate control unit.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a block diagram showing a climate management system for a power supply system according to the preferred embodiment of the present invention;

FIG. 2 is a circuit diagram of the power supply system of FIG. 1;

FIG. 3A schematically illustrates a cabinet with a waterproof and dust-reduction mechanism;

FIG. 3A shows the cooling airflow passing through the cabinet of FIG. 3A;

FIG. 4A is a front view illustrating the front panel assembly of FIG. 3A;

FIG. 4B is a rear view illustrating the front panel assembly of FIG. 3A;

FIG. 4C shows the cooling airflow passing through the front panel assembly of FIGS. 3A and 3B; and

FIG. 5 is a flowchart illustrating the management method for the climate management system of FIG. 1.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

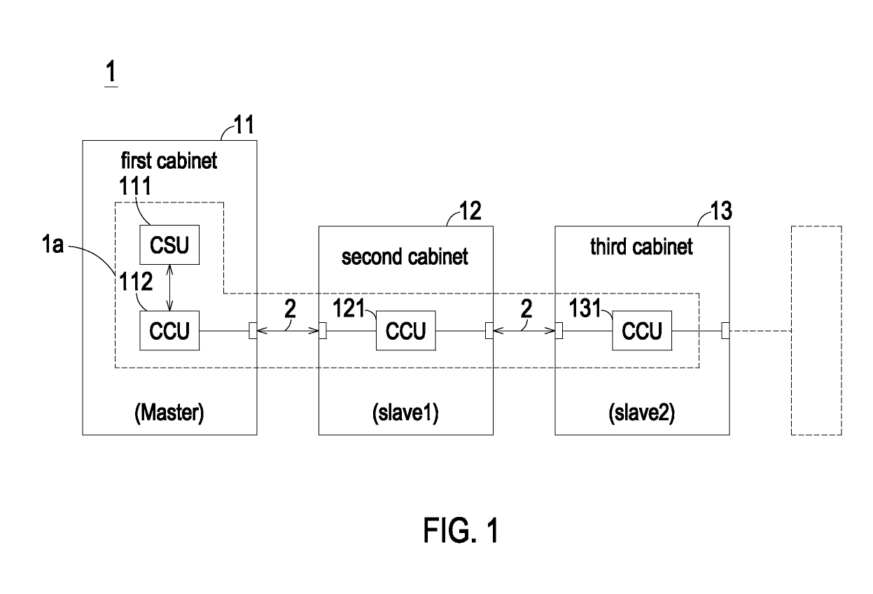

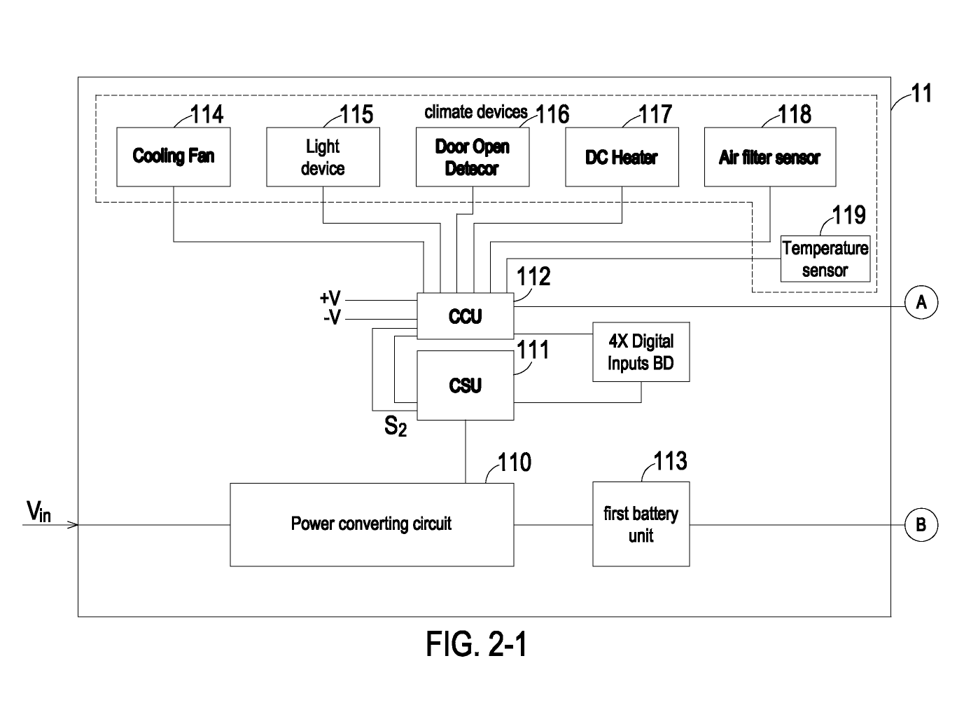

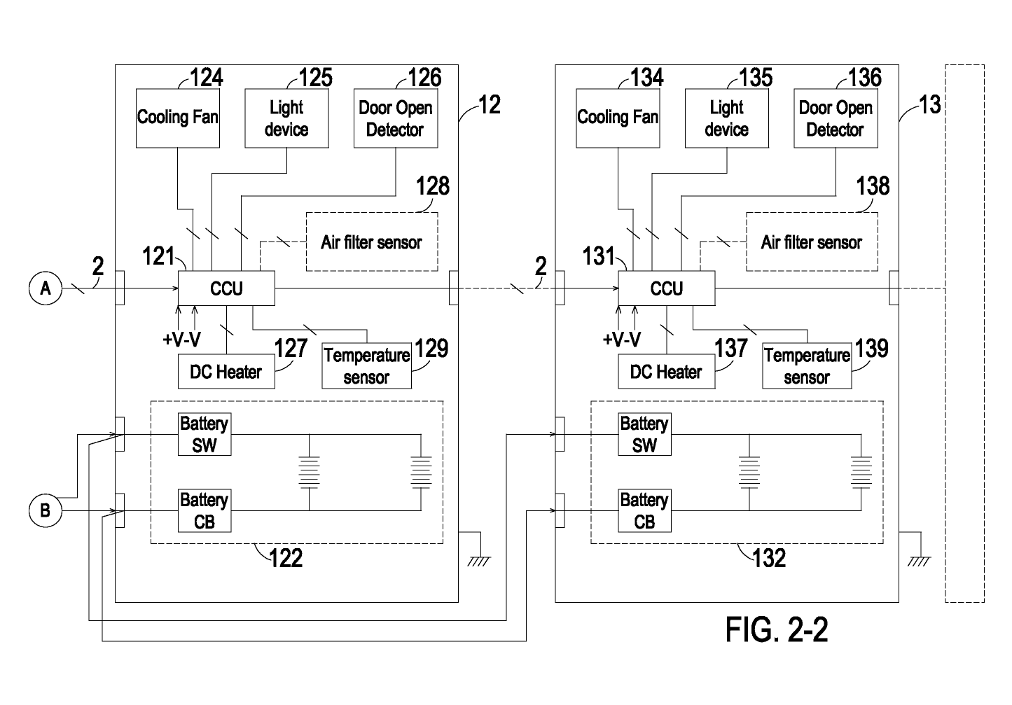

FIG. 1 is a block diagram showing a climate management system for a power supply system according to the preferred embodiment of the present invention; and FIG. 2 is a circuit diagram of the power supply system of FIG. 1. As shown in FIGS. 1 and 2, the power supply system 1 includes a plurality of cabinets, which are connected in series and may be spaced many meters apart with each other. In an embodiment, the power supply system 1 is a telecommunication power supply system, but it is not limited thereto. In an embodiment, the power supply system 1 includes three cabinets for example a first cabinet 11, a second cabinet 12 and a third cabinet 13, but it is not limited thereto. The first cabinet 11 includes a power converting unit 110, a control system unit (CSU) 111, a first climate control unit (CCU) 112 and a first battery unit 113. The second cabinet 12 includes a second climate control unit 121 and a second battery unit 122. The third cabinet 13 includes a third climate control unit 131 and a third battery unit 132. The first battery unit 113, the second battery unit 122 and the third battery unit 132 can include a battery switch and a battery circuit breaker (CB), respectively. The power supply system 1 includes a climate management system 1a, which comprises a control system unit for example the control system unit (CSU) 111 and a plurality of climate control units for example the first climate control unit (CCU) 112, the second climate control unit (CCU) 121 and the third climate control unit (CCU) 131. The first climate control unit 112 can be defined as or configured as a master climate control unit by adjusting the jumper thereof, and the second climate control unit 121 and the third climate control unit 131 can be defined as or configured as slave climate control units. The master climate control unit 112 (i.e. the first climate control unit) is coupled with the slave climate control units 121, 131 (i.e. the second and third climate control units) in series and is in communication with the slave climate control units 121, 131 via communication interfaces 2 for example RJ-485, CAN or I²C communication interfaces. Each climate control unit 112, 121, 131 is configured to monitor, manage and control the respective cabinet 11, 12, 13, for example monitoring the status of the respective backup battery unit 113, 122, 132 and the inner climate of the respective cabinet 11, 12, 13 and managing and controlling the climate devices for example cooling fan 114, 124, 134, light device 115, 125, 135, door open detector 116, 126, 136, DC heater 117, 127, 137, air filter sensor 118, 128, 138, temperature sensor 119, 129, 139 inside respective cabinet 11, 12, 13. The master climate control unit 112 can collect, process and integrate the information transmitted from the slave climate control units 121, 131 and report the collected, the processed and integrated information to the control system unit 122 via a 4× digital inputs board in an analog signal (i.e. high or low level signal) or simple digital signals. The information may include climate device alarms (in an analog signal) and battery temperature information (in simple digital signals). The second climate control unit 121 and the third climate control unit 131 are configured to collect and integrate the information of respective cabinets and report the collected and integrated information to the master climate control unit 112 through the communication interfaces 2.

The power converting unit 110 of the first cabinet 11 is electrically coupled with the first battery unit 113, the second battery unit 122 of the second cabinet 12 and the third battery units 132 of the third cabinet 13 in series. The power converting unit 110 of the first cabinet 11 is configured to receive the electrical energy from a power source and convert the electrical energy into DC voltage required to power the loads. The battery units 113, 122, 132 of the cabinets 11, 12, 13 are configured to provide necessary emergency power to the telecommunication system.

Each of the cabinets 11, 12, 13 includes a plurality of climate devices including, but not limited to, at least one cooling fan 114, 124, 134, at least one light device 115, 125, 135, at least one door open detector 116, 126, 136, at least one DC heater 117, 127, 137, at least one air filter sensor 119, 129, 139, and at least one temperature sensor 119, 129, 139. The climate devices are coupled to respective climate control unit 112, 121, 131 of respective cabinets 11, 12, 13. Each climate control unit 112, 121, 131 can monitor the status of the respective backup battery unit 113, 122, 132 and the inner climate of the respective cabinets 11, 12, 13, manage and control the climate devices, and collect and integrate the information from the climate devices.

In an embodiment, each climate control unit 112, 121, 131 can perform battery temperature compensation and battery temperature detection, and some information for example the highest battery temperature among the battery units 113, 122, 132 will be reported to the control system unit 111 via the master climate control unit 112 in simple digital signals. The climate control unit 112, 121, 131 can also perform climate device alarm detection, and the master climate control unit 112 will combine all climate device alarms and report to the control system unit 111 in simple digital signals. Each climate control unit 112, 121, 131 can also perform PWM control function so as to achieve fan cooling control. In an embodiment, the control system unit 111 can send a battery test signal S2 to the master climate control unit 112, and the master climate control unit 112 will send a corresponding battery test signal to the slave climate control units 122, 132 for turning off each climate devices in respective cabinet 11, 12, 13 so as to extend battery back up time and perform a battery remanding capacity calculation during the battery test.

According to one aspect of the present invention, the climate control unit of the cabinet can be stand alone application or can be connected with different kinds of control system units. When the climate control unit is stand alone in one cabinet, it can self control the climate devices according to the cabinet temperature or external trigger signal, for example the cabinet temperature, binary signal, . . . etc (e.g. Fan speed control, Heater turn on/off, Light on/off . . . etc), and it can also detect the alarm of climate devices. User can get alarm message easily via LED indicators (not shown in FIG. 2) and binary outputs. For special application (e.g. battery test start . . . etc), which just needs to input a simple binary signal into climate control unit for event trigger. In addition, for two or more climate control units in two or more cabinets, the climate control units can also communicate with each other without control system unit controller (CSU). Each climate control unit would self control respective cabinet, and master climate control unit would combine alarm status and temperature for all slave climate control units. User can get all cabinet information via master climate control unit (Just need to check master climate control unit). For special application (e.g. battery test start . . . etc), which just needs to input a simple binary signal into the master climate control unit. Then, the master climate control unit would notice others slave climate control units via communication protocol.

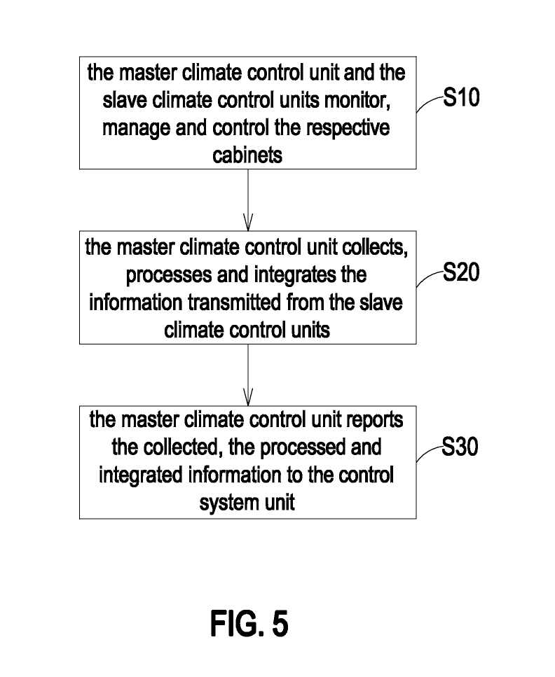

Next, the process of the management method of the climate management system 1a is illustrated. Referring to FIG. 5, the flowchart illustrating the management method for climate management system of FIG. 1 is depicted in FIG. 5. In the beginning, the master climate control unit 112 and the slave climate control units 121, 131 monitor, manage and control the respective cabinets 11, 12, 13, as shown in step S10. Next, the master climate control unit 112 collects, processes and integrates the information transmitted from the slave climate control units 121, 131, as shown in step S20. Finally, the master climate control unit 112 reports the collected, the processed and integrated information to the control system unit 122, as shown in step S30.

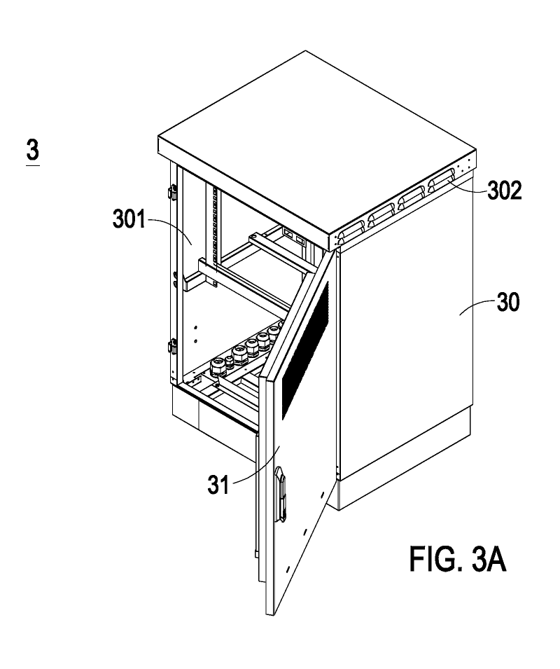

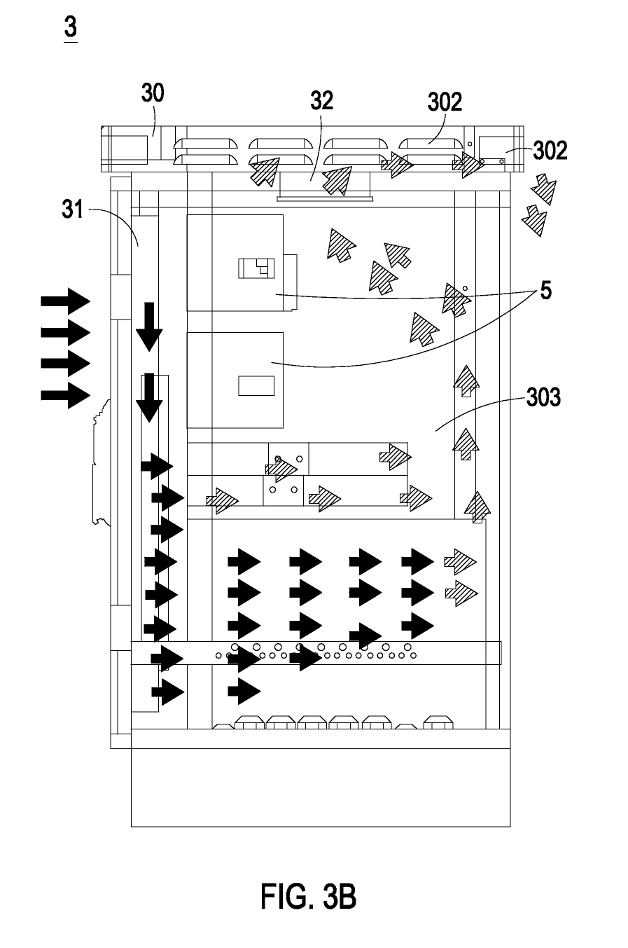

FIG. 3A schematically illustrates a cabinet with a waterproof and dust-reduction mechanism; and FIG. 3B shows the cooling airflow passing through the cabinet of FIG. 3A. As shown in FIGS. 3A and 3B, the cabinet 3 (for example one of first cabinet 11, second cabinet 12 and third cabinet 13 shown in FIG. 1) includes a main body 30, a front panel assembly 31 and a cooling fan 32. The front panel assembly 31 is employed as a waterproof and dust-reduction mechanism for the cabinet 3. The main body 30 includes a front opening 301 and one or more airflow outlet 302. The airflow outlet 302 may be disposed at the upper portion of the main body 30. The cooling fan 32 is disposed in the main body 30 and adjacent to the airflow outlet 302. The front panel assembly 31 is pivotally connected to the main body 30 for covering the front opening 301 of the main body 30 and configured to perform waterproof and dust-reduction function for the cabinet 3 when the cooling airflow is introduced.

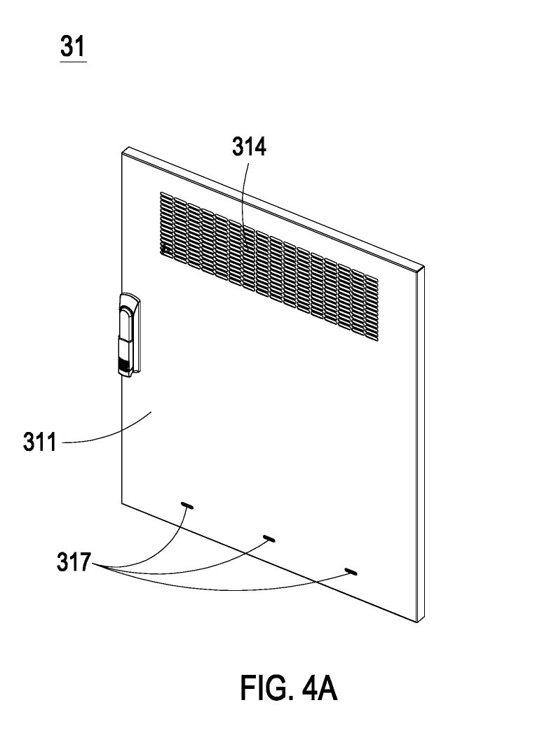

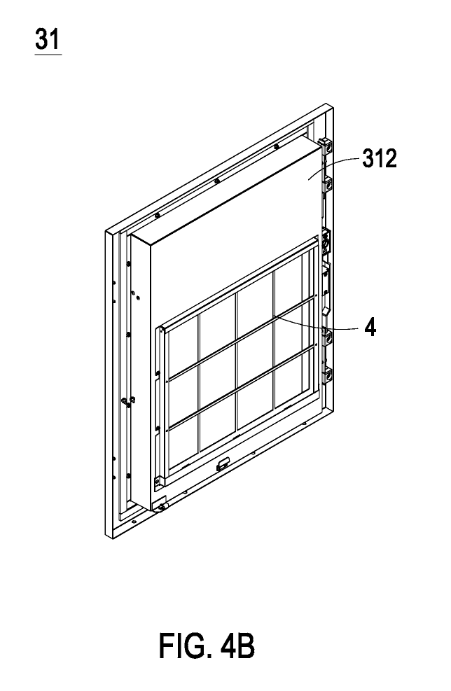

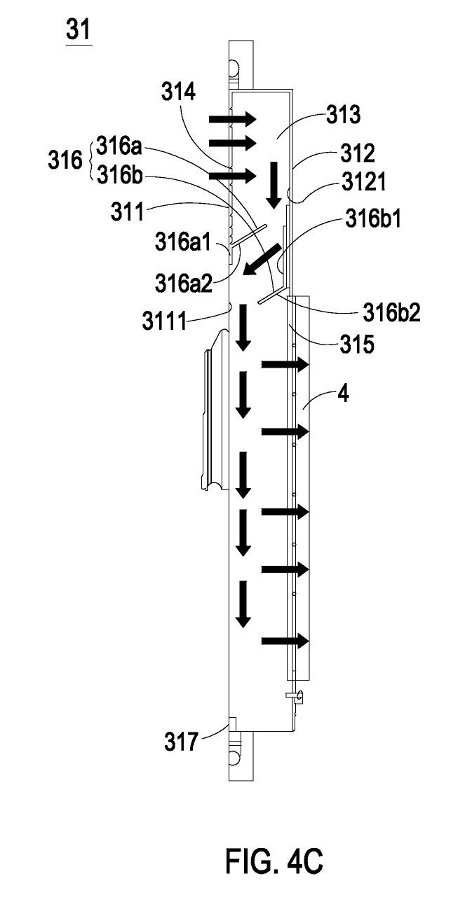

FIG. 4A is a front view schematically illustrating the front panel assembly of FIG. 3A; FIG. 4B is a rear view schematically illustrating the front panel assembly of FIG. 3A; and FIG. 4C shows the cooling airflow passing through the front panel assembly of FIGS. 3A and 3B. As shown in FIGS. 3A, 3B, 4A, 4B and 4C, the front panel assembly 31 includes a front wall 311, a back wall 312 and an airflow channel 313 formed between the front wall 311 and the back wall 312. The front wall 311 includes an airflow inlet 314 disposed on the upper area of the front wall 311. The back wall 312 includes an opening 315 disposed on the lower area of the back wall 312. The airflow inlet 314 and the opening 315 are in fluid communication with the airflow channel 313. The airflow inlet 314 of the front wall 311 is offset with the opening 315 of the back wall 312. The front panel assembly 31 includes an air filter unit 4 (i.e. dust-proof element) secured to the back wall 312 and facing to the opening 315 of the back wall 312. The air filter unit 4 is configured to filter the dust contained in the cooling airflow. The front panel assembly 31 further includes a plurality of baffles 316 disposed in the airflow channel 313 and spaced apart with each other. In an embodiment, the front panel assembly 31 includes a first baffle 316a secured on the first side 3111 of the front wall 311 and adjacent to the airflow inlet 314 and a second baffle 316b secured on the first side 3121 of the back wall 312 and disposed between the first baffle 316a and the opening 315. The first baffle 316a includes a connection portion 316a1 for connecting with and securing to the first side 3111 of the front wall 311 and an extending portion 316a2 inclined extending upwardly and toward the first side 3121 of the back wall 312. The second baffle 316b includes a connection portion 316b1 for connecting with and securing to the first side 3121 of the back wall 312 and an extending portion 316b2 inclined extending downwardly and toward the first side 3111 of the front wall 311.

The airflow inlet 314 includes a plurality ventilation holes. The front panel assembly 1 includes one or more water drain holes 317 formed at the front wall 311 and disposed at the lower area of the front wall 311. The water drain hole 317 is in fluid communication with the airflow channel 313, the opening 315 of the back wall 312 is disposed between the second baffle 316b and the water drain holes 317, and the water drain holes 317 are disposed adjacent to the bottom of the airflow channel 313.

Please refer to FIGS. 3A, 3B, 4A, 4B and 4C again. When the chilly airflow is introduced into the interior 303 of the cabinet 3 to cool the electronic devices, which are installed in the interior 303 of the cabinet, the chilly airflow can pass through the airflow inlet 314 and flow into the airflow channel 313 of the front panel assembly 31. Then, the chilly airflow flowing inside the airflow channel 313 is obstructed by the first baffle 316a and the second baffle 316b for separating the dust and moisture from the chilly airflow so that the dust and moisture will drop to the bottom of the airflow channel 313 and the chilly airflow will be directed to pass through the air filter unit 4 for further filtering the dust contained in the chilly airflow. By using the baffles 316, the dust and moisture contained in the chilly airflow can be removed in advance so that the use life of the air filter unit 4 can be extended. The chilly airflow passing through the air filter unit 4 can be directed into the interior 303 of the cabinet 3 for cooling the electronic devices 5. The hot airflow can be exhausted out of the cabinet through the airflow outlet 302 by the driving of the fan 32.

In a case that the air filter unit has been used for a prolonged period, the degree of dust accumulation becomes more serious and thus the airflow induced by the fan fails to pass through the air filter unit. Under this circumstance, the heat-removing capability of the cabinet is reduced and the performance of the cabinet is deteriorated. For providing unobstructed airflow, the air filter unit needs to be periodically cleaned or replaced with a new one. The cabinet can employ an air filter sensor and a climate control unit for discriminating whether the air filter unit needs to be replaced. For example, a notifying signal is generated and issued to the climate control unit when the pressure of the airflow passing through the air filter is lower than a threshold value.

From the above description, the present invention provides a climate management system, and a management method and a power supply system using the same, in which the climate control unit of the cabinet can be stand alone application or can be connected with different kinds of control system units. The communication between the cabinets is performed by the climate control units of the power cabinets with communication protocol for long distance communication. The master climate control unit can collect and combine all the information from the slave climate control units and transmits the integrated information to a control system unit in analog or simple digital signals. Moreover, the designer can use various control system unit in the cabinet without editing the programs according to various communication protocols between the control system unit and climate control units so that the developmental periods of the products are shortened and the manufacturing costs of the products are reduced.

In addition, the present invention also provides a cabinet having a waterproof and dust-reduction mechanism for reducing the dust and providing waterproof function and having an air filter sensor and a climate control unit for discriminating whether the dust-proof element needs to be replaced and issuing a notifying signal to the climate control unit. The waterproof and dust-reduction mechanism for the cabinet can extend the use life of the air filter unit, provide waterproof function, and reduce the acoustic noise.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A climate management system for a power supply system, wherein said power supply system includes a plurality of cabinets, said climate management system comprising:
a plurality of climate control units connected and in communication with each other, wherein each of said climate control units is disposed in a corresponding cabinet of said cabinets to monitor, manage and control said corresponding cabinet, wherein one of said climate control units is defined as a master climate control unit and the other of said climate control units are defined as slave climate control units; and
a control system unit connected and in communication with said master climate control unit;
wherein said master climate control unit is configured to collect, process and integrate the information transmitted from said slave climate control units and report the collected, processed and integrated information to said control system unit.

2. The climate management system according to claim 1, wherein one of said climate control units is defined as said master climate control unit by adjusting a jumper thereof.

3. The climate management system according to claim 1, further comprising a plurality of communication interfaces, wherein each communication interface is connected between two of said climate control units so that said climate control units are in communication with each other via said communication interfaces.

4. The climate management system according to claim 3, wherein said communication interfaces are RJ-485, CAN or I²C communication interfaces.

5. The climate management system according to claim 1, wherein each said climate control unit is configured to monitor the status of a backup battery unit and the inner climate of said corresponding cabinet and manage and control at least one climate device of said corresponding cabinet.

6. The climate management system according to claim 5, wherein when said collected, processed and integrated information includes climate device alarms, said master climate control unit reports said information to said control system unit in simple digital signals.

7. The climate management system according to claim 5, wherein said control system unit sends a battery test signal to said master climate control unit so that said master climate control unit sends corresponding battery test signals to said slave climate control units for turning off each said climate device in said respective cabinet.

8. The climate management system according to claim 5, wherein when said climate control unit is stand alone in said corresponding cabinet, said climate control unit self controls said climate devices according to the temperature of said corresponding cabinet or an external trigger signal.

9. The climate management system according to claim 5, wherein when said collected, processed and integrated information includes battery temperature information, said master climate control unit reports said information to said control system unit in simple digital signals.

10. The climate management system according to claim 5, wherein said climate device is a cooling fan, and said respective climate control unit performs a PWM control function to control the operation of said cooling fan.

11. A power supply system comprising:
a plurality of cabinets; and
a climate management system comprising:
a plurality of climate control units connected and in communication with each other, wherein each of said climate control units is disposed in a corresponding cabinet of said cabinets to monitor, manage and control said corresponding cabinet, wherein one of said climate control units is defined as a master climate control unit and the other of said climate control units are defined as slave climate control units; and
a control system unit connected and in communication with said master climate control unit;
wherein said master climate control unit is configured to collect, process and integrate the information transmitted from said slave climate control units and report the collected, processed and integrated information to said control system unit.

12. The power supply system according to claim 11, wherein each cabinet comprises:
a main body comprising a front opening and at least one airflow outlet disposed at an upper portion thereof; and
a front panel assembly pivotally connected to said main body for covering said front opening of said main body.

13. The power supply system according to claim 12, wherein said front panel assembly comprises:
a front wall comprising an airflow inlet disposed on an upper area of said front wall;
a back wall comprising an opening disposed on a lower area of said back wall; and
an airflow channel formed between said front wall and said back wall and in fluid communication with said airflow inlet and said opening.

14. The power supply system according to claim 13, wherein said front panel assembly comprises a first baffle secured on a first side of said front wall and adjacent to said airflow inlet, and said first baffle comprises a connection portion for connecting with and securing to said first side of said front wall, and an extending portion inclined extending upwardly and toward a first side of said back wall.

15. The power supply system according to claim 14, wherein said front panel assembly comprises a second baffle secured on said first side of said back wall and disposed between said first baffle and said opening, and said second baffle comprises a connection portion for connecting with and securing to said first side of said back wall, and an extending portion inclined extending downwardly and toward said first side of said front wall.

16. The power supply system according to claim 11, wherein said power supply system is a telecommunication power supply system.

17. The power supply system according to claim 11, wherein each cabinet comprises a plurality of climate devices, and said climate devices includes a cooling fan, a light device, a door open detector, a DC heater, an air filter sensor and a temperature sensor.

18. The power supply system according to claim 17, wherein each said climate control unit is configured to monitor the status of a backup battery unit and the inner climate of said corresponding cabinet and manage and control said climate devices of said corresponding cabinet.

19. A management method of a climate management system, wherein said climate management system is applied to a power supply system having a plurality of cabinets, and said climate management system comprises a master climate control unit, a plurality of slave climate control units and a control system unit, and said master climate control unit and each said slave climate control unit are respectively disposed in a corresponding cabinet, the management method comprising the steps of:
(a) monitoring, managing and controlling said corresponding cabinet respectively by said master climate control unit and each said slave climate control unit;
(b) collecting, processing and integrating the information from said slave climate control units by said master climate control unit; and
(c) reporting the collected, processed and integrated information to said control system unit by said master climate control unit.

20. The management method according to claim 19, wherein said master climate control unit and each said climate control unit is configured to monitor the status of a backup battery unit and the inner climate of said corresponding cabinet and manage and control at least one climate device of said corresponding cabinet.
